(19) United States
(12) Patent Application Publication
(10) Pub. No.: US 2024/0203741 A1
(43) Pub. Date: Jun. 20, 2024

(54) CAVITY SHAPING AND SELECTIVE METAL SILICIDE FORMATION FOR CMOS DEVICES

(71) Applicant: Applied Materials, Inc., Santa Clara, CA (US)

(72) Inventors: Nicolas Louis BREIL, San Jose, CA (US); Avgerinos V. GELATOS, Scotts Valley, CA (US)

(21) Appl. No.: 18/388,043

(22) Filed: Nov. 8, 2023

Related U.S. Application Data
(60) Provisional application No. 63/433,154, filed on Dec. 16, 2022.

(51) Int. Cl. H01L 21/285; H01L 21/02; H01L 21/3065; H01L 29/40

(52) U.S. Cl. CPC H01L 21/28518; H01L 21/02068; H01L 21/3065; H01L 29/401; H01J 37/32357; H01J 2237/334; H01J 2237/335

(57) ABSTRACT

A method of forming an electrical contact in a semiconductor structure includes performing a cavity shaping process on a semiconductor structures having an n-type metal oxide semiconductor (n-MOS) region and a p-type MOS (p-MOS) region, the cavity shaping process comprising forming an n-MOS cavity in an exposed surface of the n-MOS region and a p-MOS cavity in an exposed surface of the p-MOS region, and performing a first selective deposition process to form a p-MOS cavity contact, selectively in the p-MOS cavity.

### CROSS-REFERENCE TO RELATED APPLICATIONS

This application claims priority to U.S. Provisional Application Ser. No. 63/433,154 filed Dec. 16, 2022, which is herein incorporated by reference in its entirety.

### BACKGROUND

### Field

Embodiments described herein generally relate to semiconductor device fabrication, and more particularly, to systems and methods of forming an electrical contact within a semiconductor structure.

### Description of the Related Art

Multi-gate metal-oxide-semiconductor field-effect transistors (MOSFETs), such as complementary metal-oxide semiconductor (CMOS) devices, pose challenges in manufacturability due to their three-dimensional (3D) designs and small sizes. In advanced CMOS devices, metal silicide (e.g. molybdenum silicide (MoSi₂), ruthenium silicide (RuₓSi_{y})) selectively formed at a bottom of a trench contact is often utilized to lower a contact resistivity, and engineering progresses to pre-clean an exposed surface of a trench contact have been made to optimize selectivity in formation of metal silicide. However, pre-clean processes by themselves have not provided sufficient selectivity in the formation of metal silicide.

Therefore, there is a need for methods and systems that can selectively form a metal silicide contact in a trench contact for CMOS devices.

### SUMMARY

Embodiments of the present disclosure provide a method of forming an electrical contact in a semiconductor structure. The method includes performing a cavity shaping process on a semiconductor structures having an n-type metal oxide semiconductor (n-MOS) region and a p-type MOS (p-MOS) region, the cavity shaping process comprising forming an n-MOS cavity in an exposed surface of the n-MOS region and a p-MOS cavity in an exposed surface of the p-MOS region, and performing a first selective deposition process to form a p-MOS cavity contact, selectively in the p-MOS cavity.

Embodiments of the present disclosure also provide a method of forming an electrical contact in a semiconductor structure. The method includes performing a pre-clean process on a semiconductor structures having an n-type metal oxide semiconductor (n-MOS) region, a p-type metal oxide semiconductor (p-MOS) region, and a dielectric layer having a first trench over the n-MOS region and a second trench over the p-MOS region, performing a cavity shaping process to form an n-MOS cavity in an exposed surface of the n-MOS region within the first trench and a p-MOS cavity in an exposed surface of the p-MOS region within the second trench, performing a first selective deposition process to form a p-MOS cavity contact, selectively in the p-MOS cavity, performing a second selective deposition process to form an n-MOS cavity contact, selectively in the n-MOS cavity, performing a blanket deposition process to form a barrier layer on exposed inner surfaces of the first trench and the second trench and on the exposed surface of the dielectric layer, and performing a metal fill process to form a first contact plug in the first trench and a second contact plug in the second trench.

Embodiments of the present disclosure further provide a processing system. The processing system includes a first processing chamber, a second processing chamber, and a system controller configured to cause the processing system to perform, in the first processing chamber, a cavity shaping process on a semiconductor structures having an n-type metal oxide semiconductor (n-MOS) region and a p-type metal oxide semiconductor (p-MOS) region, the cavity shaping process comprising forming an n-MOS cavity in an exposed surface of the n-MOS region and a p-MOS cavity in an exposed surface of the p-MOS region, and perform, in the second processing chamber, a first selective deposition process to form a p-MOS cavity contact, selectively in the p-MOS cavity.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIG. 2A is a cross sectional view of a processing chamber, according to one or more embodiments.

FIG. 2B is an enlarged view of a portion of the processing chamber of FIG. 2A.

FIG. 3 depicts a process flow diagram of a method of forming a contact layer in a semiconductor structure according to one or more embodiments of the present disclosure.

FIGS. 4A, 4B, 4C, 4D, 4E, and 4F are cross-sectional views of a portion of a semiconductor structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods and systems for forming an electrical contact that includes metal silicide (e.g. molybdenum silicide (MoSi₂), ruthenium silicide (RuₓSi_{y})) at a selected portion (e.g., on an exposed surface of a layer of silicon germanium) of a structure that is used to form a CMOS device. The methods and systems may be particularly useful for forming, in a semiconductor structure having a region that includes silicon, a region that includes silicon germanium, a dielectric layer formed thereover, and a metal silicide contact (e.g. molybdenum silicide (MoSi₂), ruthenium silicide (RuₓSi_{y})) formed selectively on an exposed surface of the silicon germanium material within an opening or feature (e.g., contact trench) in the dielectric layer. The processes described herein are configured to form cavities in the opening or feature (e.g., contact trench), surfaces of which are optimized for selective deposition of metal silicide.

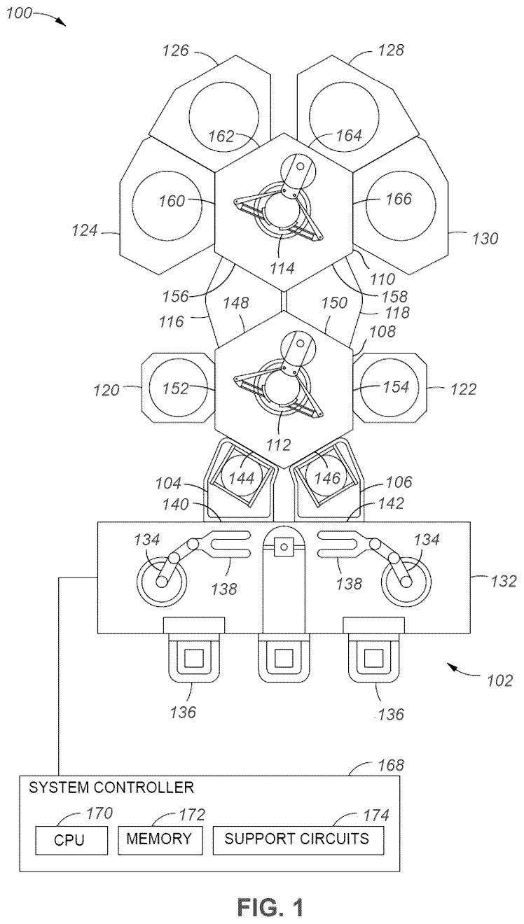

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

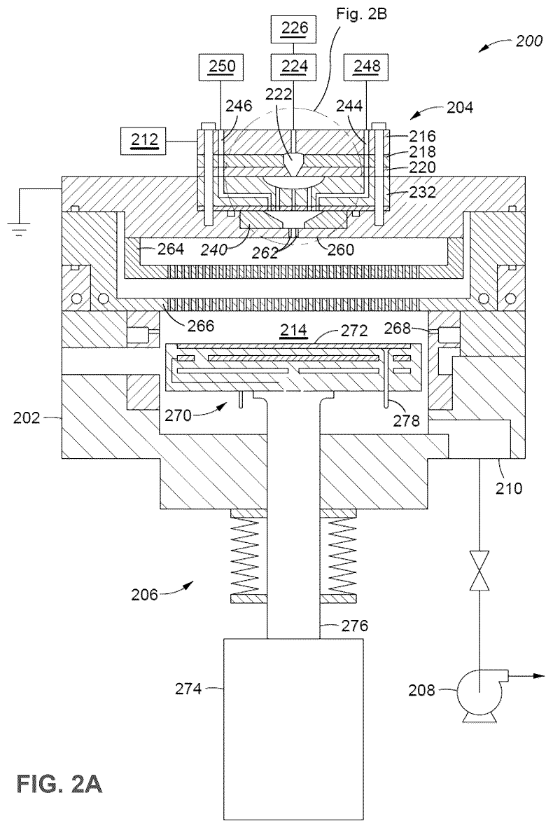

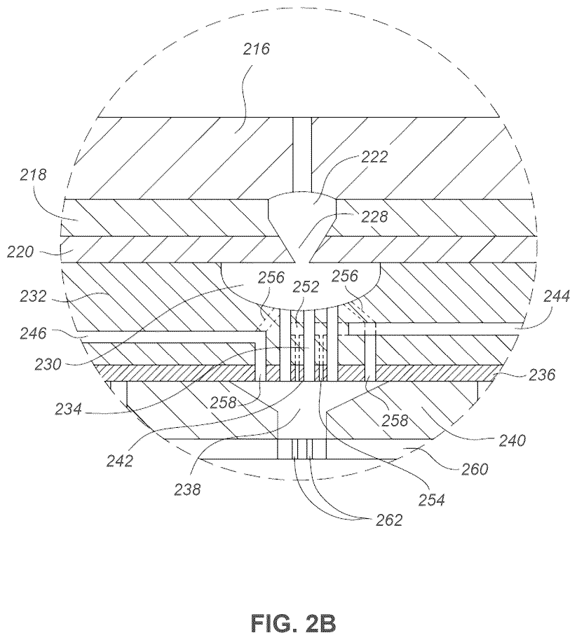

FIG. 2A is a cross sectional view of a processing chamber 200, according to one or more embodiments, that is adapted to perform a pre-clean process as detailed below. The processing chamber 200 may be the processing chamber 122 shown in FIG. 1. FIG. 2B is an enlarged view of a portion of the processing chamber 200 of FIG. 2A.

The processing chamber 200 may be particularly useful for performing a thermal or plasma-based cleaning process and/or a plasma assisted dry etch process. The processing chamber 200 includes a chamber body 202, a lid assembly 204, and a support assembly 206. The lid assembly 204 is disposed at an upper end of the chamber body 202, and the support assembly 206 is at least partially disposed within the chamber body 202. A vacuum system can be used to remove gases from processing chamber 200. The vacuum system includes a vacuum pump 208 coupled to a vacuum port 210 disposed in the chamber body 202. The processing chamber 200 also includes a controller 212 for controlling processes within the processing chamber 200.

The lid assembly 204 includes stacked components adapted to provide precursor gases and/or a plasma to a processing region 214 within the processing chamber 200. A first plate 216 is coupled to a second plate 218. A third plate 220 is coupled to the second plate 218. The lid assembly 204 may be connected to a power source (not shown) for supplying a plasma to a cone-shaped chamber 222 formed in the lid assembly 204. The lid assembly 204 can also be connected to a remote plasma source 224 that creates the plasma upstream of the lid stack. The remote plasma cavity (e.g., the processing region 214, the first plate 216, and the second plate 218 in FIGS. 2A-2B) is coupled to a gas source 226 via the remote plasma source 224 (or the gas source 226 is coupled directly to the lid assembly 204 in the absence of the remote plasma source 224). The gas source 226 may include a gas source that is adapted to provide helium, argon, or other inert gas. In some configurations, the gas provided by the gas source 226 can be energized into a plasma that is provided to the lid assembly 204 by use of the remote plasma source 224. In alternate embodiments, the gas source 226 may provide process gases that can be activated by the remote plasma source 224 prior to being introduced to a surface of the substrate that is disposed within the processing chamber 200. Referring to FIG. 2B, the cone-shaped chamber 222 has an opening 228 that allows a formed plasma to flow from the remote plasma source 224 to a volume 230 formed in a fourth plate 232 of the lid assembly 204.

In some configurations of the lid assembly 204, a plasma is generated within the cone-shaped chamber 222 by the application of energy delivered from a plasma source. In one example, the energy can be provided by biasing the lid assembly 204 to capacitively couple RF, VHF and/or UHF energy to the gases positioned in the cone-shaped chamber 222. In this configuration of the lid assembly 204, the remote plasma source 224 may not be used, or not be installed within the lid assembly 204.

A central conduit 234, which is formed in the fourth plate 232, is adapted to provide the plasma generated species provided from the volume 230 through a fifth plate 236 to a mixing chamber 238 formed in a sixth plate 240 of the lid assembly 204. The central conduit 234 communicates with the mixing chamber 238 through an opening 242 in the fifth plate 236. The opening 242 may have a diameter less than, greater than or the same as a diameter of the central conduit 234. In the embodiment of FIG. 2B, the opening 242 has diameter the same as the central conduit 234.

The fourth plate 232 also includes inlets 244 and 246 that are adapted to provide gases to the mixing chamber 238. The inlet 244 is coupled to a first gas source 248 and the inlet 246 is coupled to a second gas source 250. The first gas source 248 and the second gas source 250 may include processing gases as well as inert gases, for example inert gases such as argon and/or helium, utilized as a carrier gas. The first gas source 248 may include ammonia (NH₃) as well as argon (Ar). The second gas source 250 may contain fluorine containing gases, hydrogen containing gases, or a combination thereof. In one example, the second gas source 250 may contain hydrogen fluoride (HF) as well as argon (Ar).

As illustrated in FIG. 2B, in some configurations, the inlet 244 is coupled to the mixing chamber 238 through a cylindrical channel 252 (shown in phantom) and holes 254 formed in the fifth plate 236. The inlet 246 is coupled to the mixing chamber 238 through a cylindrical channel 256 (shown in phantom) and holes 258 formed in the fifth plate 236. The holes 254, 258 formed in the fifth plate 236 are generally sized so that they enable a uniform flow of gases, which are provided from their respective gas source 248, 250, into the mixing chamber 238. In one configuration, the holes 258 have a diameter that is less than a width of the opening defined by the opposing sidewalls of the cylindrical channel 256 formed in the fourth plate 232. The holes 258 are typically distributed around the circumference of the center-line of the cylindrical channel 256 to provide uniform fluid flow into the mixing chamber 238. In one configuration, the holes 254 have a diameter that is less than a width of the opening defined by the opposing sidewalls of the cylindrical channel 252 formed the fourth plate 232. The holes 254 are typically distributed around the circumference of the center-line of the cylindrical channel 252 to provide uniform fluid flow into the mixing chamber 238.

The inlets 244 and 246 provide respective fluid flow paths laterally through the fourth plate 232, turning toward and penetrating through the fifth plate 236 to the mixing chamber 238. The lid assembly 204 also includes a seventh plate or first gas distributor 260, which may be a gas distribution plate, such as a showerhead, where the various gases mixed in the lid assembly 204 are flowed through perforations 262 formed therein. The perforations 262 are in fluid communication with the mixing chamber 238 to provide flow pathways from the mixing chamber 238 through the first gas distributor 260.

Referring back to FIG. 2A, a blocker plate 264 and a gas distribution plate, such as a second gas distributor 266, which may be a gas distribution plate, such as a showerhead, is disposed below the lid assembly 204.

Alternatively, a different cleaning process may be utilized to clean the substrate surface. For example, a remote plasma containing helium (He) and ammonia (NH₃) may be introduced into the processing chamber 200 through the lid assembly 204, while ammonia (NH₃) may be directly injected into the processing chamber 200 via a separate gas inlet 268 that is disposed at a side of the chamber body 202 and coupled to a gas source (not shown).

The support assembly 206 may include a substrate support 270 to support a substrate 272 thereon during processing. The substrate support 270 may be coupled to an actuator 274 by a shaft 276 which extends through a centrally-located opening formed in a bottom of the chamber body 202. The actuator 274 may be flexibly sealed to the chamber body 202 by bellows (not shown) that prevent vacuum leakage around the shaft 276. The actuator 274 allows the substrate support 270 to be moved vertically within the chamber body 202 between a processing position and a loading position. The loading position is slightly below the opening of a tunnel (not shown) formed in a sidewall of the chamber body 202.

The substrate support 270 has a flat, or a substantially flat, substrate supporting surface for supporting a substrate 272 to be processed thereon. The substrate support 270 may be moved vertically within the chamber body 202 by the actuator 274, which is coupled to the substrate support 270 by the shaft 276. For some process operations, the substrate support 270 may be elevated to a position in close proximity to the lid assembly 204 to control the temperature of the substrate 272 being processed. As such, the substrate 272 may be heated via radiation emitted from the second gas distributor 266, or another radiant source, or by convection or conduction from the second gas distributor 266 through an intervening gas. In some process steps, the substrate may be disposed on lift pins 278 to perform additional thermal processing operations, such as performing an annealing step.

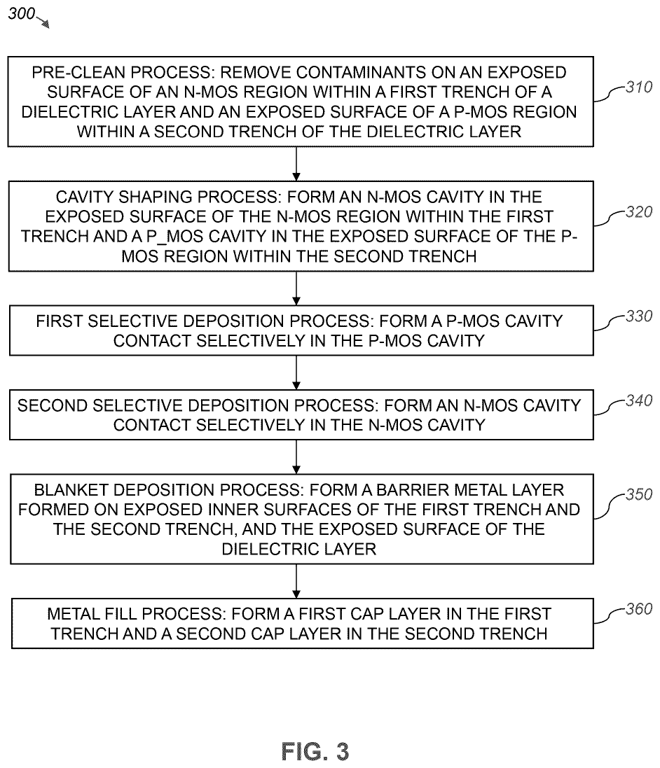

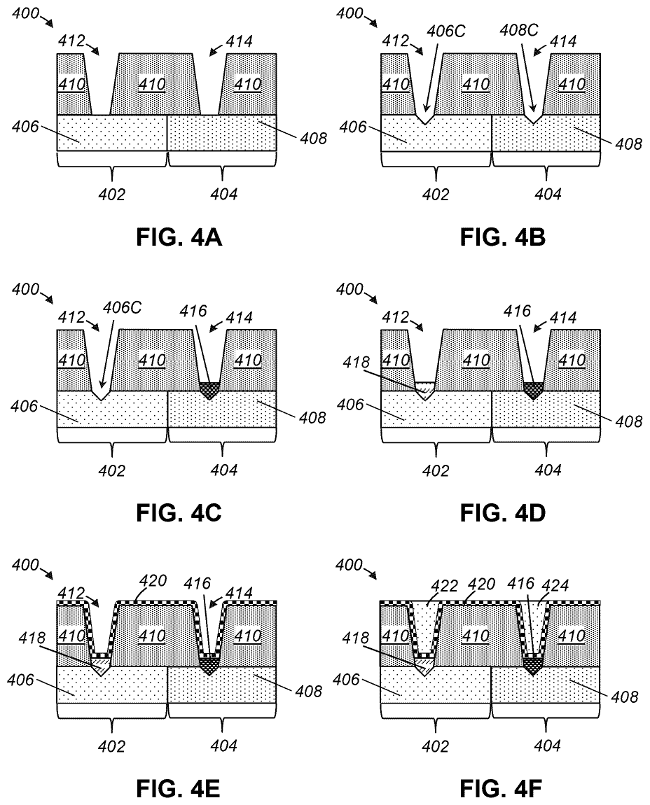

FIG. 3 depicts a process flow diagram of a method 300 of forming a contact layer in a semiconductor structure 400 according to some embodiments of the present disclosure. FIGS. 4A, 4B, 4C, 4D, 4E, and 4F are cross-sectional views of a portion of the semiconductor structure 400 corresponding to various states of the method 300. It should be understood that FIGS. 4A, 4B, 4C, 4D, 4E, and 4F illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

Referring to FIGS. 4A, 4B, 4C, 4D, 4E, and 4F, the semiconductor structure 400 may include an n-type MOS device 402 and a p-type MOS device 404 formed on a substrate (not shown).

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 4A, a portion of an n-type MOS device 402 of a plurality of n-type transistor devices formed on the substrate includes an n-type metal oxide semiconductor (n-MOS) region 406 formed of a first material, such as silicon (Si). A portion of a p-type MOS device 404 of a plurality of p-type transistor devices formed on the substrate includes a p-type MOS (p-MOS) region 408 formed of a second material, such as silicon germanium (SiGe). The first and second materials include materials having differing compositions, such that the second material can be selectively etched relative to the first material (i.e., an etch rate of the second material is higher than an etch rate of the first material). The etch selectivity of the second material (i.e., a ratio of the etch rate of the second material to the etch rate of the first material) is between about 10:1 to 500:1. Other example combinations of the first material and the second material include silicon (Si)/silicon germanium (SiGe), germanium (Ge)/silicon germanium (SiGe), or silicon (Si)/germanium tin (GeSn), respectively.

The n-MOS regions 406 may be doped with n-type dopants such as phosphorus (P), antimony (Sb), with the concentration between about 10²⁰ cm⁻³ and 5·x10²¹ cm⁻³, depending upon the desired conductive characteristic of the n-type MOS device 402. The p-MOS regions 408 may be doped with p-type dopants such as boron (B) or gallium (Ga), with the concentration of between about 10²⁰ cm⁻³ and about 5·x10²¹ cm⁻³, depending upon the desired conductive characteristic of the p-type MOS device 404.

The semiconductor structure 400 further includes a dielectric layer 410 having a first trench 412 formed over the n-MOS region 406 and a second trench 414 formed over the p-MOS region 408. The dielectric layer 410 may be formed of a dielectric material, such as silicon dioxide (SiO₂) or silicon nitride (Si₃N₄).

The n-MOS region 406 and the p-MOS region 408 may be formed using any suitable deposition technique, such as epitaxial (Epi) deposition, chemical vapor deposition (CVD), atomic layer deposition (ALD), or physical vapor deposition (PVD), and the first and second trenches 412 and 414 are formed by a patterning technique, such as a lithography and etch process.

The method 300 begins with a pre-clean process in block 310. The pre-clean process may be performed in a processing chamber, such as the processing chamber 122 shown in FIG. 1, or the processing chamber 200 shown in FIG. 2. The pre-clean process in block 310 may be performed without breaking vacuum environment in a multi-chamber processing system, such as the multi-chamber processing system 100 shown in FIG. 1.

The pre-clean process is configured to remove contaminants, such as carbon-containing contaminants (e.g., patterning residues), or oxide-containing contaminants (e.g., native oxide layers) formed on the exposed surface of the n-MOS region 406 within the first trench 412 and the exposed surface of the p-MOS region 408 within the second trench 414.

The pre-clean process to remove carbon-containing contaminants may include an anisotropic remote plasma assisted dry etch process, such as a reactive ion etching (RIE) process, using a plasma formed from a gas including hydrogen (H), argon (Ar), helium (He), or a combination thereof. The plasma effluents directionally bombard and remove a remaining dielectric layer within the first trench 412 and the second trench 414.

The pre-clean process to remove oxide-containing contaminants may include an isotropic plasma etch process, such as a dry chemical etch process, using amorphous hydrofluoric acid (HF) and ammonia (NH₃), or a SiCoNi™ dry etch process, using a plasma formed from a gas including ammonia (NH₃), nitrogen trifluoride (NF₃). The dry etch process is selective for oxide layers, and thus does not readily etch silicon, germanium, or nitride layers regardless of whether the layers are amorphous, crystalline or polycrystalline. Selectivity of the dry etch process for oxide versus silicon or germanium is at least about 3:1, and usually 5:1 or better, sometimes 10:1. The dry etch process is also highly selective of oxide versus nitride. The selectivity of the dry etch process versus nitride is at least about 3:1, usually 5:1 or better, sometimes 10:1.

In block 320, a cavity shaping process is performed to form an n-MOS cavity 406C in the exposed surface of the n-MOS region 406 within the first trench 412 and a p-MOS cavity 408C in the exposed surface of the p-MOS region 408 within the second trench 414, as shown in FIG. 4B. The cavity shaping process may be performed in an etch chamber, such as the processing chamber 120 shown in FIG. 1. The cavity shaping process in block 320 may be performed without breaking vacuum environment in a multi-chamber processing system, such as the multi-chamber processing system 100 shown in FIG. 1.

The cavity shaping process in block 320 includes an etch process using an etching gas including halogen-containing gas, such as chlorine (Cl₂), hydrogen chloride (HCl), or hydrogen fluoride (HF), and carrier gas, such as include argon (Ar), or helium (He). An etch process using chlorine (Cl₂) and hydrogen (H₂) is sensitive to the amount of germanium (Ge), and thus this cavity shaping process reacts differently on the n-MOS region 406 (e.g., silicon (Si)) and the p-MOS region 408 (e.g., silicon germanium (SiGe)). This difference may cause the difference in deposition rates of metal material on the exposed surface on the n-MOS cavity 406C (e.g., silicon (Si)) and the exposed surface on the p-MOS cavity 408C (e.g., silicon germanium (SiGe)) in the subsequent selective deposition processes.

The n-MOS and p-MOS cavities 406C and 408C may have a V-shape, a U-shape, or any other shape, having a width of between about 5 nm and about 15 nm and a depth of between about 5 nm and about 15 nm, and enlarge a contact area between the p-MOS region 408 and a contact plug to be formed within the second trench 414, to minimize parasitic resistance, leading to an improved device performance.

The cavity shaping process is used to refresh (e.g., etching a surface of about a few nanometers that is potentially contaminated with remaining oxygen, nitrogen, or carbon) and prepare pure contamination free exposed surfaces of the n-MOS and p-MOS cavities 406C and 408C on which a contact (e.g., metal silicide) can be formed selectively within the p-MOS cavity 408C in a subsequent deposition process. The cavity shaping process is also used to optimize a device stress.

In block 330, a first selective deposition process is performed to form a p-MOS cavity contact 416 selectively in the p-MOS cavity 408C, as shown in FIG. 4C. The first selective deposition process may be performed in a processing chamber, such as the processing chamber 126, 128, or 130 shown in FIG. 1. The first selective deposition process in block 330 may be performed without breaking vacuum environment in a multi-chamber processing system, such as the multi-chamber processing system 100 shown in FIG. 1.

The p-MOS cavity contact 416 may be formed of a first metal material, such as molybdenum (Mo), ruthenium (Ru), or silicide thereof. The p-MOS cavity contact 416 interfaces with the p-MOS region 408 and a contact plug to be formed within the second trench 414, and provides an electrical connection therebetween.

In some embodiments, the first selective deposition process includes a deposition process, such as chemical vapor deposition (CVD), physical vapor deposition (PVD), or the like. The selectivity in the first selective deposition process may arise from differences in reactions of a deposition precursor of the first metal material (e.g., molybdenum (Mo), ruthenium (Ru)) with the exposed surface of the n-MOS cavity 406C (e.g., silicon (Si), passivated silicon (Si) surface) and the exposed surface of the p-MOS cavity 408C (e.g., silicon germanium (SiGe)). During the deposition process, the deposition precursor reacts preferentially with the exposed surface of the p-MOS cavity 408C (e.g., silicon germanium (SiGe)) to the exposed surface of the n-MOS cavity 406C (e.g., silicon (Si), passivated silicon (Si) surface), and thus growth of the first metal material may occur at a faster rate on the exposed surface of the p-MOS cavity 408C than the exposed surface of the n-MOS cavity 406C.

In some embodiments, a deposition gas used in the deposition process includes a metal source, such as a molybdenum (Mo)-containing halide precursor, or a ruthenium (Ru)-containing organometallic that includes ruthenium (Ru). The first selective deposition process may be performed at a temperature of between about 240° C. and about 450° C. and at a pressure of between 3° Torr and 300° Torr. During the deposition process, argon (Ar) gas may be supplied at a flow rate of between about 0 sccm and about 1000 sccm, and hydrogen (H₂) gas may be supplied at a flow rate of between about 500 sccm and about 15000 sccm, for example.

A cycle of the first selective deposition process may be repeated as needed to obtain a desired thickness of the p-MOS cavity contact 416, for example, between about 5 times and about 1000 times.

In block 340, a second selective deposition process is optionally performed to form an n-MOS cavity contact 418 selectively in the n-MOS cavity 406C, as shown in FIG. 4D. The second selective deposition process may be performed in a processing chamber, such as the processing chamber 126, 128, or 130 shown in FIG. 1. The second selective deposition process in block 340 may be performed without breaking vacuum environment in a multi-chamber processing system, such as the multi-chamber processing system 100 shown in FIG. 1.

The n-MOS cavity contact 418 may be formed of a second metal material, such as titanium (Ti), cobalt (Co), nickel (Ni), tantalum (Ta), lanthanum (La), yttrium (Y), hafnium (Hf), zirconium (Zr), or silicide thereof. The n-MOS cavity contact 418 interfaces with the n-MOS region 406 and a contact plug to be formed within the first trench 412, and provides an electrical connection therebeween.

In some embodiments, the second selective deposition process includes a deposition process, such chemical vapor deposition (CVD), physical vapor deposition (PVD), or the like. The selectivity in the second selective deposition process may arise from differences in reactions of a deposition precursor of the second metal material (e.g., titanium (Ti)) with the exposed surface of the n-MOS cavity 406C (e.g., silicon (Si)) and the exposed surface of the p-MOS cavity contact 416 (e.g., molybdenum (Mo), ruthenium (Ru)). During the deposition process, the deposition precursor reacts preferentially with the exposed surface of the n-MOS cavity 406C (e.g., silicon (Si)) to the exposed surface of the p-MOS cavity contact 416 (e.g., molybdenum (Mo), ruthenium (Ru)), and growth of the second metal material may occur at a faster rate on the exposed surface of the n-MOS cavity 406C than the exposed surface of the p-MOS cavity contact 416 (e.g., molybdenum (Mo), ruthenium (Ru)).

In some embodiments, a deposition gas used in the deposition process includes a metal source, such as a precursor containing titanium (Ti), tantalum (Ta), cobalt (Co), nickel (Ni), combination thereof. The second selective deposition process may be performed at a temperature of between about 300° C. and about 800° C. and at a pressure of between 1° Torr and 50° Torr.

In block 350, a blanket deposition process is performed to form a barrier metal layer 420 on the exposed inner surfaces of the first trench 412 and the second trench 414, and the exposed surface of the dielectric layer 410, as shown in FIG. 4E. The barrier metal layer 420 protects the p-MOS cavity contact 416 and the n-MOS cavity contact 418 and allows nucleation and growth of contact plugs in the first trench 412 and the second trench 414. The barrier metal layer 420 may be formed of a barrier metal material that is titanium nitride (TiN), or tantalum nitride (TaN). In some embodiments, the n-MOS cavity contact 418 is a silicide layer that is formed from a portion of the barrier metal layer 420 by use of a spike anneal process. The blanket deposition process in block 350 may be performed without breaking vacuum environment in a multi-chamber processing system, such as the multi-chamber processing system 100 shown in FIG. 1.

In block 360, a metal fill process is performed to form a first contact plug 422 in the first trench 412 and a second contact plug 424 in the second trench 414, as shown in FIG. 4F. The first contact plug 422 and the second contact plug 424 may be formed of contact plug metal material, such as tungsten (W), cobalt (Co), ruthenium (Ru), or molybdenum (Mo). The first contact plug 422 and the second contact plug 424 may include a metal that has a desirable work function. The metal fill process in block 360 may include a chemical vapor deposition (CVD) process using a tungsten-containing precursor, such as WF₆, or a cobalt-containing precursor, in a processing chamber, such as the processing chamber 126, 128, or 130 shown in FIG. 1.

After the metal fill process, the semiconductor structure 400 may be planarized, by use of a chemical mechanical planarization (CMP) process.

The embodiments described herein provide methods and system for forming an electrical contact that includes metal silicide (e.g. molybdenum silicide (MoSi₂), ruthenium silicide (RuₓSi_{y})) within a trench on a selected portion of a transistor structure. The contact trench structure includes a metal contact plug formed within a trench between adjacent device modules, and electrical contacts that interface between the contact plug and silicon-based channels in the device modules, reducing parasitic resistance. The electrical contacts are formed by a selective deposition. The electrical contact may be of metal silicide (e.g. molybdenum silicide (MoSi₂), ruthenium silicide (RuₓSi_{y})) selectively formed in a trench in a p-type MOS device (e.g., silicon germanium), or of metal silicide (e.g., titanium silicide (Ti Si₂)) selectively formed in a trench in a n-type MOS device. Due to the cavity shaping process according to the embodiments described herein, to form a cavity within the trench, a contact interface area is increased and exposed surfaces of the cavity are optimized for selective deposition of metal silicide within the cavity.

While the foregoing is directed to embodiments of the present disclosure, other and further embodiments of the disclosure may be devised without departing from the basic scope thereof, and the scope thereof is determined by the claims that follow.

1. A method of forming an electrical contact in a semiconductor structure, comprising:
performing a cavity shaping process on a semiconductor structures having an n-type metal oxide semiconductor (n-MOS) region and a p-type MOS (p-MOS) region, the cavity shaping process comprising forming an n-MOS cavity in an exposed surface of the n-MOS region and a p-MOS cavity in an exposed surface of the p-MOS region; and
performing a first selective deposition process to form a p-MOS cavity contact, selectively in the p-MOS cavity.

2. The method of claim 1, wherein
the n-MOS region comprises silicon doped with n-type dopants, and
the p-MOS region comprises silicon germanium doped with p-type dopants.

3. The method of claim 2, wherein
the cavity shaping process comprises:
an etch process using chlorine (Cl₂) and hydrogen (H₂).

4. The method of claim 1, wherein
the p-MOS cavity contact comprises material selected from molybdenum (Mo) silicide and ruthenium (Ru) silicide.

5. The method of claim 1, further comprising:
prior to the cavity shaping process, performing a pre-clean process, comprising:
removing carbon-containing contaminants from the exposed surfaces of the n-MOS region and the p-MOS region, by a dry etch process using hydrogen (H) plasma; and
removing oxide-containing contaminants from the exposed surfaces of the n-MOS region and the p-MOS region, by a dry etch process.

6. The method of claim 1, further comprising:
subsequent to the first selective deposition process, performing a second selective deposition process to form an n-MOS cavity contact, selectively in the n-MOS cavity.

7. The method of claim 6, wherein
the n-MOS cavity contact comprises titanium (Ti) silicide.

8. The method of claim 1, wherein
the first selective deposition process is performed without breaking vacuum environment.

9. A method of forming an electrical contact in a semiconductor structure, comprising:
performing a pre-clean process on a semiconductor structures having an n-type metal oxide semiconductor (n-MOS) region, a p-type metal oxide semiconductor (p-MOS) region, and a dielectric layer having a first trench over the n-MOS region and a second trench over the p-MOS region;
performing a cavity shaping process to form an n-MOS cavity in an exposed surface of the n-MOS region within the first trench and a p-MOS cavity in an exposed surface of the p-MOS region within the second trench;
performing a first selective deposition process to form a p-MOS cavity contact, selectively in the p-MOS cavity;
performing a second selective deposition process to form an n-MOS cavity contact, selectively in the n-MOS cavity;
performing a blanket deposition process to form a barrier layer on exposed inner surfaces of the first trench and the second trench and on the exposed surface of the dielectric layer; and
performing a metal fill process to form a first contact plug in the first trench and a second contact plug in the second trench.

10. The method of claim 9, wherein the pre-clean process, the cavity shaping process, the first selective deposition process, the second selective deposition process, and the blanket deposition process are performed without breaking vacuum environment.

11. The method of claim 9, wherein
the n-MOS region comprises silicon doped with n-type dopants, and
the p-MOS region comprises silicon germanium doped with p-type dopants.

12. The method of claim 11, wherein
the cavity shaping process comprises:
an etch process using chlorine (Cl₂) and hydrogen (H₂).

13. The method of claim 9, wherein
the p-MOS cavity contact comprises material selected from molybdenum (Mo) silicide and ruthenium (Ru) silicide, and
the n-MOS cavity contact comprises titanium (Ti) silicide.

14. The method of claim 9, wherein the pre-clean process comprises:
removing carbon-containing contaminants from the exposed surfaces of the n-MOS region and the p-MOS region, by a dry etch process using hydrogen (H) plasma; and
removing oxide-containing contaminants from the exposed surfaces of the n-MOS region and the p-MOS region, by a dry etch process.

15. The method of claim 9, wherein the barrier layer comprises titanium nitride (TiN), or tantalum nitride (TaN).

16. The method of claim 9, the first contact plug and the second contact plug comprise tungsten (W).

17. A processing system, comprising:
a first processing chamber;
a second processing chamber; and
a system controller configured to cause the processing system to:
perform, in the first processing chamber, a cavity shaping process on a semiconductor structures having an n-type metal oxide semiconductor (n-MOS) region and a p-type metal oxide semiconductor (p-MOS) region, the cavity shaping process comprising forming an n-MOS cavity in an exposed surface of the n-MOS region and a p-MOS cavity in an exposed surface of the p-MOS region; and
perform, in the second processing chamber, a first selective deposition process to form a p-MOS cavity contact, selectively in the p-MOS cavity.

18. The processing system of claim 17, further comprising:
a third processing chamber, wherein the system controller is further configured to:
prior to the cavity shaping process, perform, in the third processing chamber, a pre-clean process, comprising:
removing carbon-containing contaminants from the exposed surfaces of the n-MOS region and the p-MOS region, by a dry etch process using hydrogen (H) plasma; and
removing oxide-containing contaminants from the exposed surfaces of the n-MOS region and the p-MOS region, by a dry etch process.

19. The processing system of claim 17, further comprising:
a fourth processing chamber, wherein the system controller is further configured to:
subsequent to the first selective deposition process, perform, in the fourth processing chamber, a second selective deposition process to form an n-MOS cavity contact, selectively in the n-MOS cavity.

20. The processing system of claim 17, wherein the system controller is further configured to cause the processing system to perform the cavity shaping process and the first selective deposition process without breaking vacuum environment.
